(19) United States
(12) Patent Application Publication
(10) Pub. No.: US 2026/0323835 A1
(43) Pub. Date: Oct. 15, 2026

(54) HOUSING CONFIGURATION FOR MULTIPLE CHOKES

(71) Applicant: Goodrich Corporation, Charlotte, NC (US)

(72) Inventors: Jinan Krishnan Ottuvallil, Bangalore (IN); Ashish Kumar Agarwal, Bangalore (IN); Sanjay Kumarapuram Anantharaman, Bangalore (IN)

(73) Assignee: Goodrich Corporation, Charlotte, NC (US)

(21) Appl. No.: 19/533,798

(22) Filed: Feb. 9, 2026

(30) Foreign Application Priority Data
Apr. 15, 2025 (IN) 202541036332

(51) Int. Cl. H05K 1/181; H01F 27/24; H01F 27/28

(52) U.S. Cl. CPC H05K 1/181; H01F 27/24; H01F 27/28; H05K 2201/1003

(57) ABSTRACT

A multiple-choke housing assembly is disclosed. The multiple-choke housing assembly includes a housing, a plurality of chokes, and a lid. The housing comprising a plurality of voids. Each of plurality of voids is configured to receive one of the plurality of chokes. The lid is configured to couple to the housing and enclose the plurality of chokes.

### CROSS-REFERENCE TO RELATED APPLICATIONS

This application claims priority to, and the benefit of, India Provisional Patent Application No. 202541036332, filed Apr. 15, 2025 (DAS Code EB96) and titled “HOUSING CONFIGURATION FOR MULTIPLE CHOKES,” which is incorporated by reference herein in its entirety for all purposes.

### FIELD

The present disclosure generally relates to the field of chokes and, more particularly, to a housing configuration for multiple chokes.

### BACKGROUND

Typical designs for packaging and implementation of electrical components, such as chokes, also referred to as inductors, is important for optimizing space, performance, and manufacturability. Typical designs for packaging and implementation for chokes involves housing each choke in an individual enclosure. However, housing each choke in an individual enclosure increases a consumption of materials due to separate enclosures for each choke, occupies more space on a printed circuit board or circuit card due to multiple individual enclosures resulting in a bulkier design, increases production complexity and costs due to multiple enclosures, increases production time and associated labor due to assembly of the individual chokes and the associated housings, necessitates increased space requirements along with additional mounting and clearance space, and/or increases electrical noise interference when choke assemblies are placed closely together in a layout.

### SUMMARY

According to various embodiments of the present disclosure, a multiple-choke housing assembly is provided. The multiple-choke housing assembly includes a housing, a plurality of chokes, and a lid. The housing includes a plurality of voids. Each of plurality ofvoids is configured to receive one of the plurality of chokes. The lid is configured to couple to the housing and enclose the plurality of chokes.

In various embodiments, the housing is constructed from a material. In various embodiments, the material is at least one of Aluminum, Magnesium, or Copper.

In various embodiments, each void in the plurality of voids comprises a shape to correspond to a shape of the choke that will reside therein. In various embodiments, responsive to a choke in the plurality of chokes being disposed in the void in the plurality of voids, a clearance is provided for securing the choke within the void.

In various embodiments, the choke is secured within the void via a potting material.

In various embodiments, a first void of plurality of voids and a second void of the plurality of voids share a common wall. In various embodiments, a thickness of the common wall is between 0.0625 inches (0.1588 centimeter) and 0.5 inches (1.27 centimeters).

In various embodiments, each choke of the plurality of chokes includes a plurality of windings.

In various embodiments, each winding of the plurality of windings is configured with a first extended lug on a first end of the winding and a second extended lug on a second end of the winding.

In various embodiments, the lid is configured with a plurality of openings.

In various embodiments, the first extended lug and the second extended lug are configured to extend through a respective opening of the plurality of openings.

In various embodiments, the lid is comprised of a non-conductive material.

In various embodiments, the housing includes a set of threaded holes configured to mount the lid to the housing.

In various embodiments, the housing includes a set of alignment tabs. In various embodiments, the lid includes a set of alignment indents. In various embodiments, the set of alignment tabs and the set of alignment indents are configured to align the lid with the housing.

Also according to various embodiments of the present disclosure, a component within an aircraft is provided. The component includes a printed circuit board and a multiple-choke housing assembly coupled to the printed circuit board. The multiple-choke housing assembly includes a housing, a plurality of chokes, and a lid. The housing includes a plurality of voids. Each of plurality of voids is configured to receive one of the plurality of chokes. The lid is configured to couple to the housing and enclose the plurality of chokes.

In various embodiments, the housing is constructed from a material. In various embodiments, the material is at least one of Aluminum, Magnesium, or Copper.

In various embodiments, each void in the plurality of voids comprises a shape to correspond to a shape of the choke that will reside therein. In various embodiments, responsive to a choke in the plurality of chokes being disposed in the void in the plurality of voids, a clearance is provided for securing the choke within the void. In various embodiments, the choke is secured within the void via a potting material.

In various embodiments, a first void of plurality of voids and a second void of the plurality of voids share a common wall. In various embodiments, a thickness of the common wall is between 0.0625 inches (0.1588 centimeter) and 0.5 inches (1.27 centimeters).

In various embodiments, each choke of the plurality of chokes includes a plurality of windings. In various embodiments, each winding of the plurality of windings is configured with a first extended lug on a first end of the winding and a second extended lug on a second end of the winding. In various embodiments, the lid is configured with a plurality of openings. In various embodiments, the first extended lug and the second extended lug are configured to extend through a respective opening of the plurality of openings.

In various embodiments, the lid is comprised of at least one of a polycarbonate; an epoxy; or a flame-resistant, fiberglass-reinforced epoxy laminate.

In various embodiments, the housing includes at least one through hole configured for mounting the multiple-choke housing assembly to a printed circuit board.

In various embodiments, the housing includes a set of threaded holes configured to mount the lid to the housing. In various embodiments, the housing includes a set of alignment tabs. In various embodiments, the lid includes a set of alignment indents. In various embodiments, the set of alignment tabs and the set of alignment indents are configured to align the lid with the housing.

The present disclosure may include any one or more of the individual features disclosed above and/or below alone or in any combination thereof.

The foregoing features and elements may be combined in various combinations without exclusivity, unless expressly indicated herein otherwise. These features and elements as well as the operation of the disclosed embodiments will become more apparent in light of the following description and accompanying drawings.

### BRIEF DESCRIPTION OF THE DRAWINGS

The subject matter of the present disclosure is particularly pointed out and distinctly claimed in the concluding portion of the specification. A more completeunderstanding of the present disclosure, however, may best be obtained by referring to the following detailed description and claims in connection with the following drawings. While the drawings illustrate various embodiments employing the principles described herein, the drawings do not limit the scope of the claims.

FIG. 1 illustrates a side view of an aircraft in which a multiple-choke housing assembly may be implemented, in accordance with various embodiments.

FIG. 2 illustrates a front view of an aircraft in which a multiple-choke housing assembly may be implemented, in accordance with various embodiments.

FIG. 3 illustrates an isometric view of a multiple-choke housing assembly with four chokes, in accordance with various embodiments.

FIG. 4 illustrates an exploded view of a multiple-choke housing assembly with four chokes, in accordance with various embodiments.

FIG. 5 illustrates an isometric view of a multiple-choke housing assembly with two chokes, in accordance with various embodiments.

FIG. 6 illustrates an exploded view of a multiple-choke housing assembly with two chokes, in accordance with various embodiments.

FIG. 7 illustrates an isometric view of a multiple-choke housing assembly with six chokes, in accordance with various embodiments.

FIG. 8 illustrates an exploded view of a multiple-choke housing assembly with six chokes, in accordance with various embodiments.

### DETAILED DESCRIPTION

The following detailed description of various embodiments herein makes reference to the accompanying drawings, which show various embodiments by way of illustration. While these various embodiments are described in sufficient detail to enable those skilled in the art to practice the disclosure, it should be understood that other embodiments may be realized and that changes may be made without departing from the scope of the disclosure. Thus, the detailed description herein is presented for purposes of illustration only and not of limitation. Furthermore, any reference to singular includes plural embodiments, and any reference to more than one component or step may include a singular embodiment or step. Also, any reference to attached, fixed, connected, or the like may include permanent, removable, temporary, partial, full or any other possible attachment option. Additionally, any reference to without contact (or similar phrases) may also include reduced contact or minimal contact. It should also be understood that unless specificallystated otherwise, references to “a,” “an,” or “the” may include one or more than one and that reference to an item in the singular may also include the item in the plural. Further, all ranges may include upper and lower values and all ranges and ratio limits disclosed herein may be combined.

Disclosed herein are methods and systems for a multiple-choke housing configuration. That is, the disclosed multiple-choke housing configuration provides a smaller form factor with low material weight eliminating electrical interference noise and avoiding assembly deviations in PCB assembly. In various embodiments, the innovative design groups multiple-choke assemblies into a single housing which adheres to both electrical and mechanical requirements related to reliability. Unlike typical designs, in various embodiments, the disclosed multiple-choke housing configuration consolidates two or more chokes into a single unit.

In various embodiments, the disclosed multiple-choke housing configuration houses multiples of two chokes; however, the illustrative embodiments are not limited to only multiples of two. In that regard, the disclosed multiple-choke housing configuration may house any number of chokes greater than one choke. Accordingly, in various embodiments, the disclosed multiple-choke housing configuration reduces space requirements by housing multiple chokes in a single housing assembly which reduces the weight associated with multiple housings and thereby offering a more compact solution without compromising on performance.

Further, by housing multiple chokes in a single housing assembly, material consumption may be reduced, overall form factor may be decreased by providing for a more efficient use of space on the PCB, production and assembly costs may be lowered by simplifying the manufacturing process and reducing the number of individual parts, an assembly process may be simplified by reducing labor and time required to integrate the chokes into the housing, performance and protection may be ensured through effective thermal management and electromagnetic interference (EMI) shielding provided by the housing, and/or material usage and manufacturing efficiency may be reduced, which contributes to a lower environmental footprint.

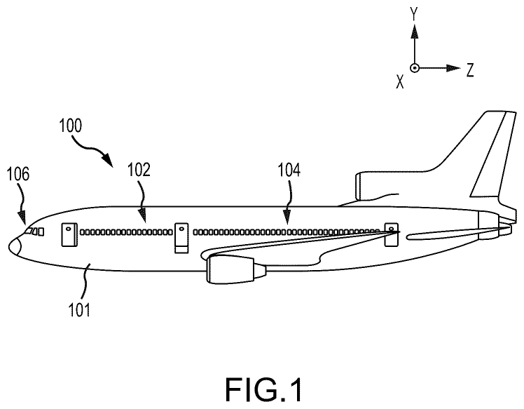

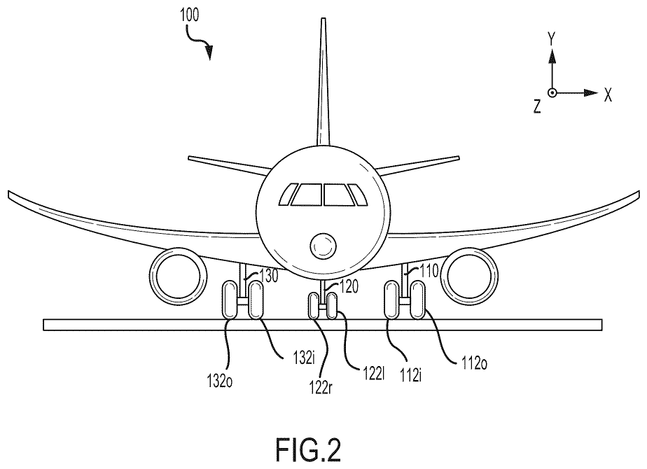

Referring now to FIGS. 1 and 2, in accordance with various embodiments, a side view and a front view, respectively, of an aircraft 100 in which a multiple-choke housing assembly may be implemented is illustrated. In various embodiments and with particular reference to FIG. 1, the aircraft 100 includes a fuselage 101 having or defining one or more enclosed spaces such as a first passenger cabin 102, a second passenger cabin 104, and acockpit 106. In various embodiments and with particular reference to FIG. 2, the aircraft 100 includes multiple landing gears, i.e., a first landing gear 110, a second landing gear 120, and a third landing gear 130, is illustrated.

In various embodiments, the first landing gear 110, second landing gear 120, and third landing gear 130 each include one or more wheel assemblies. In various embodiments, the second landing gear 120, which is also a nose landing gear for the aircraft 100, includes a left wheel assembly 122L and a right wheel assembly 122R. In various embodiments, the first landing gear 110 includes an inboard wheel assembly 112i and an outer wheel assembly 112o, and the third landing gear 130 includes an inner wheel assembly 132i and an outer wheel assembly 132o.

The first landing gear 110, second landing gear 120, and third landing gear 130 support the aircraft 100 when the aircraft 100 is not airborne, thereby allowing the aircraft 100 to take off, land, and taxi. In various embodiments, the second landing gear 120 is also a nose landing gear for the aircraft 100, and often times, one or more of the first landing gear 110, second landing gear 120, and third landing gear 130 are operationally retractable into the aircraft 100 when the aircraft 100 is in flight and/or airborne.

In various embodiments and with reference to FIGS. 1 and 2, a multiple-choke housing assembly may be utilized in association with multiple components within the aircraft 100. In various embodiments, the multiple-choke housing assembly may be utilized in light assemblies, air/ventilation assemblies, or notification assemblies, among others utilized in one or more of the first passenger cabin 102, the second passenger cabin 104, and the cockpit 106. In various embodiments, the multiple-choke housing assembly may be utilized in power supplies or motor drives, among other associated with the first landing gear 110, second landing gear 120, and third landing gear 130. It is noted that while the multiple-choke housing assembly is described with regard to assemblies in the first passenger cabin 102, the second passenger cabin 104, and the cockpit 106 and/or the first landing gear 110, second landing gear 120, and third landing gear 130, the illustrative embodiments are not limited to only these components as the multiple-choke housing assembly may be utilized in associated within any component with aircraft 100 where multiple chokes would have conventionally been used.

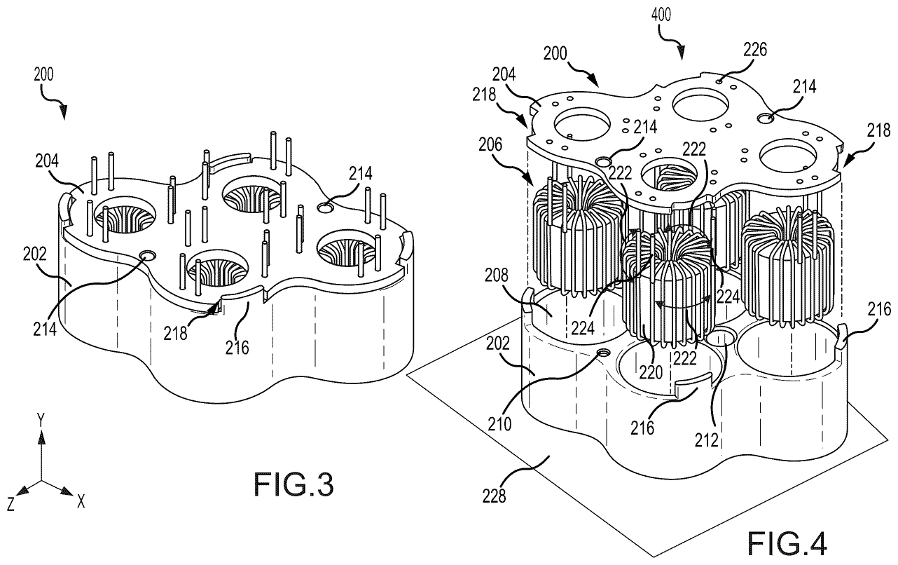

Referring now to FIGS. 3 and 4, in accordance with various embodiments, an isometric view and an exploded view, respectively, of a multiple-choke housing assembly with four chokes is illustrated. In various embodiments, the multiple-choke housing assembly 200 includes housing 202, lid 204, and two or more chokes 206, also referred to as inductors.In various embodiments, the housing 202 includes two or more voids 208, each void of the two or more voids 208 configured to receive one choke of the two or more chokes 206. In various embodiments, each void of the two or more voids 208 has at least one of a substantially cylindrical shape, decagon shape, or octagon shape to coincide with the at least one of a substantially cylindrical shape, decagon shape, or octagon shape of the associated choke. In that regard, each void in the two or more voids 208 within the housing 202 may be configured to coincide or conform with a shape of a respective choke and thereby provide for receiving any typical choke shape.

In various embodiments, the housing 202 may be constructed from material such as Aluminum, Magnesium, or Copper, among other materials. In various embodiments, the Aluminum may be the alloy known as American Society for Testing and Materials (ASTM) Aluminum 6061-T654. In that regard, the type of material utilized in the manufacturing of the housing 202 is chosen based on an environment in which the multiple-choke housing assembly 200 may be installed. In various embodiments, the housing 202 may be formed from a block of the material and machined to form the desired shape of the housing 202. In various embodiments, the housing 202 may be formed by pouring the melted material into a die and then machined to form the desired shape of the housing 202.

In various embodiments, the final desired shape of the housing includes the two or more voids 208 where each void of the two or more voids 208 shares a common wall with at least one other void of the two or more voids 208. In various embodiments, a smallest thickness, i.e., in a Z-direction and/or a X-direction, of the common wall between each void of the two or more voids 208 may be between 0.0625 inches (0.1588 centimeter) and 0.5 inches (1.27 centimeters). In various embodiments, the smallest thickness of the common wall between each void of the two or more voids 208 may be between 0.125 inches (0.3175 centimeter) and 0.375 inches (0.9525 centimeter). In various embodiments, the smallest thickness of the common wall between each void of the two or more voids 208 may be between 0.25 inches (0.635 centimeter) and 0.375 inches (0.9525 centimeter). In various embodiments, dimensions of the two or more voids and the smallest thickness of the common wall may be determined based on the choke dimensions and other clearance requirement to provide space optimization and to place the multiple-choke housing assembly 200 as close as possible within a defined area based on electrical routing convenience.

In various embodiments, the housing 202 may include one or more threaded holes 210 as well as one or more through holes 212. In various embodiments, the one or more threaded holes 210 are configured to received screws that attach the lid 204 to the housing202 via holes 214 in the lid 204. In various embodiments, the one or more through holes 212 are configured to receive screws or other attachment mechanisms that couple the housing 202 to a printed circuit board (PCB) 228. In various embodiments, the threaded holes 210 extend into housing 202 less than a thickness of the housing 202. In various embodiments, the through holes 212 extend through the housing 202 the full thickness of the housing 202.

In that regard, in various embodiments, the one or more through holes 212 may be unthreaded through an entire thickness, in a Y-direction, of the housing 202 so that, prior to the lid 204 being attached, a screw may pass through the hole and into a threaded attachment mechanism on the PCB. In various embodiments, the one or more through holes 212 may be threaded through an entire thickness, in a Y-direction, of the housing 202 so that a screw may pass through the PCB and into the threaded hole of the housing 202.

In various embodiments, the housing 202 may include one or more alignment tabs 216 that along with one or more alignment indents 218 in the lid 204. In that regard, in various embodiments, when the lid 204 is attached to the housing 202, the one or more alignment indents 218 in the lid 204 are configured to align with the one or more alignment tabs 216 on the housing 202. In various embodiments, the lid 204 may be composed of a non-conductive material such as a polycarbonate; an epoxy; or a flame-resistant, fiberglass-reinforced epoxy laminate, among others. In that regard, the type of material utilized in the manufacturing of the lid 204 is chosen based on an environment in which the multiple-choke housing assembly 200 may be installed. In various embodiments, the lid 204 includes openings 226 though which extended lugs 224, i.e., the ends of the windings 222 described hereafter, pass so as to provide solder leads. In that regard, the lid 204 is composed of a non-conductive material.

In various embodiments, each choke of the two or more chokes 206 includes a core 220 and two or more sets of windings 222. While in FIG. 4 each choke of the two or more chokes 206 is shown with three sets of windings, the illustrative embodiments, are not limited to three sets of windings. In that regard, each choke of the two or more chokes 206 may include as little as two windings or any number greater than two windings, such as three, four, or five windings, among others, as long as the number of windings is greater than two. In various embodiments, a beginning and an end of each winding of the two or more sets of windings 222 is coupled to an extended lug of the extended lugs 224, which is configured to extend upward, in a Y-direction, so that, when the lid 204 is attached to the housing 202, each of the extended lugs 224 extends through the lid 204. In various embodiments, each of theextended lugs 224 provides for a solder point via the exterior of the multiple-choke housing assembly 200 which may reduce electrical creepage from solder point to housing 202.

In various embodiments, each of the two or more voids 208 may extend all the way thorough the housing 202 in the Y-direction or substantially all of way through the housing 202 in the Y-direction. In that regard, a portion of the housing 202 may remain in a bottom of each void of the two or more voids 208 so that each choke of the two or more chokes 206 may rest on the remaining portion of the housing 202. In either scenario, in various embodiments, once the two or more chokes 206 are disposed within and associated one of the two or more voids 208, each of the two or more chokes 206 may be secured within its associated void via a potting material configured to secure each of the two or more chokes 206 to the housing 202. In that regard, each void of the two or more voids 208 may be configured with a clearance to accommodate an amount of potting material to secure the associated choke to the housing 202.

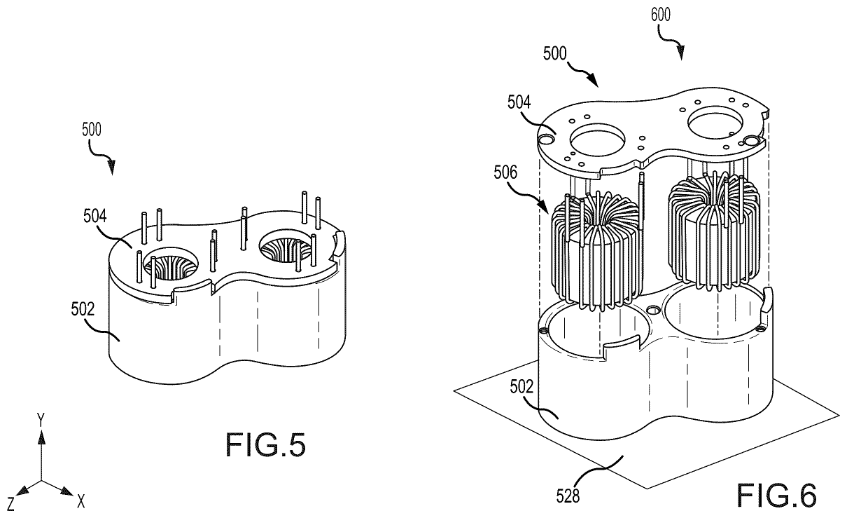

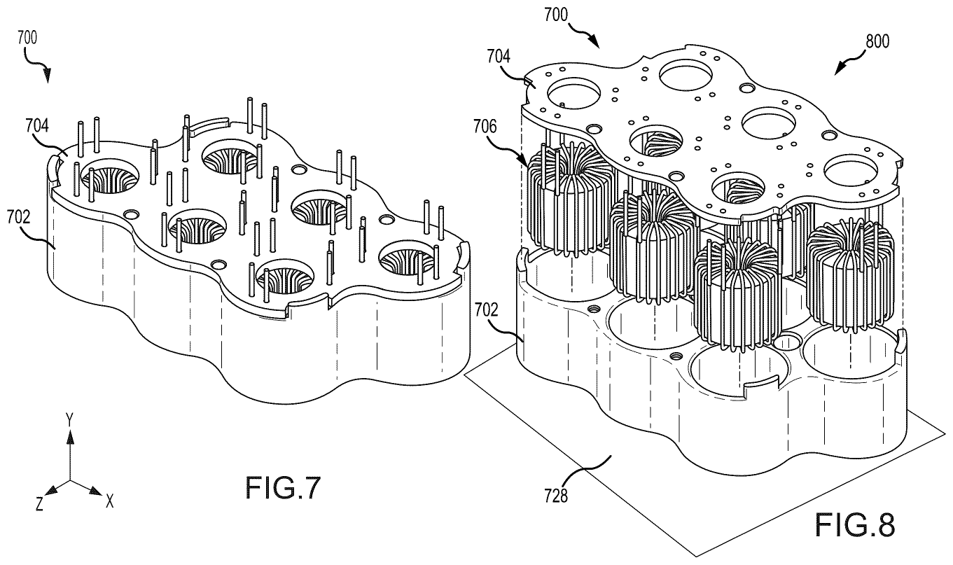

While in FIGS. 3 and 4 a multiple-choke housing configuration housing four chokes is illustrated, as discussed previously, in various embodiments, the multiple-choke housing configuration may comprise any number of chokes greater than one. In that regard, in accordance with various embodiments, the multiple-choke housing configuration may house four chokes as is illustrated in FIGS. 3 and 4, in accordance with various embodiments, the multiple-choke housing configuration may house two chokes as is illustrated in FIGS. 5 and 6, or, in accordance with various embodiments, the multiple-choke housing configuration may house six chokes as is illustrated in FIGS. 7 and 8. The multiple-choke housing assembly 500 and component 600 of FIGS. 5 and 6 and the multiple-choke housing assembly 700 and component 800 of FIGS. 7 and 8 are similar to the multiple-choke housing assembly 200 and component 400 of FIGS. 3 and 4. In that regard, in various embodiments, the multiple-choke housing assembly 300 of FIGS. 5 and 6 includes housing 502, lid 504, chokes 506, and PCB 528, etc., and the multiple-choke housing assembly 700 of FIGS. 7 and 8 includes housing 702, lid 704, chokes 706, and PCB 728, etc., which correspond to the same elements, i.e., housing 202, lid 204, chokes 206, and PCB 228, etc. of FIGS. 3 and 4. The only difference between the multiple-choke housing assembly 00 and component 400 of FIGS. 3 and 4 and the multiple-choke housing assembly 500 and component 600 of FIGS. 5 and 6 and the multiple-choke housing assembly 700 and component 800 of FIGS. 7 and 8 is that the multiple-choke housing assembly 200 and component 400 of FIGS. 3 and 4 includes four chokes, the multiple-choke housing assembly 500 and component 600 of FIGS. 5 and 6 includes two chokes, and the multiple-choke housing assembly 700 and component 800 ofFIGS. 7 and 8 includes six chokes. Additionally, while in the various embodiments, the disclosed multiple-choke housing configurations house multiples of two chokes, the illustrative embodiments are not limited to only multiples of two. In that regard, the disclosed multiple-choke housing configuration may house any number of chokes greater than one choke.

Benefits and other advantages have been described herein with regard to specific embodiments. Furthermore, the connecting lines shown in the various figures contained herein are intended to represent exemplary functional relationships and/or physical couplings between the various elements. It should be noted that many alternative or additional functional relationships or physical connections may be present in a practical system. However, the benefits, advantages, and any elements that may cause any benefit or advantage to occur or become more pronounced are not to be construed as critical, required, or essential features or elements of the disclosure. The scope of the disclosure is accordingly to be limited by nothing other than the appended claims, in which reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

Systems, methods, and apparatus are provided herein. In the detailed description herein, references to “one embodiment,” “an embodiment,” “various embodiments,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments.

Numbers, percentages, or other values stated herein are intended to include that value, and also other values that are about or approximately equal to the stated value, as would be appreciated by one of ordinary skill in the art encompassed by variousembodiments of the present disclosure. A stated value should therefore be interpreted broadly enough to encompass values that are at least close enough to the stated value to perform a desired function or achieve a desired result. The stated values include at least the variation to be expected in a suitable industrial process, and may include values that are within 10%, within 5%, within 1%, within 0.1%, or within 0.01% of a stated value. Additionally, the terms “substantially,” “about,” or “approximately” as used herein represent an amount close to the stated amount that still performs a desired function or achieves a desired result. For example, the term “substantially,” “about,” or “approximately” may refer to an amount that is within 10% of, within 5% of, within 1% of, within 0.1% of, and within 0.01% of a stated amount or value.

Furthermore, no element, component, or method step in the present disclosure is intended to be dedicated to the public regardless of whether the element, component, or method step is explicitly recited in the claims. No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

Finally, it should be understood that any of the above-described concepts can be used alone or in combination with any or all of the other above-described concepts. Although various embodiments have been disclosed and described, one of ordinary skill in this art would recognize that certain modifications would come within the scope of this disclosure. Accordingly, the description is not intended to be exhaustive or to limit the principles described or illustrated herein to any precise form. Many modifications and variations are possible in light of the above teaching.

What is claimed is:

1. A multiple-choke housing assembly comprising:
a plurality of chokes;
a housing comprising a plurality of voids, each of plurality of voids configured to receive a choke of the plurality of chokes; and
a lid configured to couple to the housing and enclose the plurality of chokes.

2. The multiple-choke housing assembly of claim 1, wherein the housing is constructed from a material, and wherein the material is at least one of Aluminum, Magnesium, or Copper.

3. The multiple-choke housing assembly of claim 1, wherein each void in the plurality of voids comprises a shape to correspond to a shape of the choke that will reside therein, and wherein, responsive to the choke in the plurality of chokes being disposed in the void in the plurality of voids, a clearance is provided for securing the choke within the void.

4. The multiple-choke housing assembly of claim 3, wherein the choke is secured within the void via a potting material.

5. The multiple-choke housing assembly of claim 1, wherein a first void of plurality of voids and a second void of the plurality of voids share a common wall and wherein a thickness of the common wall is between 0.0625 inches (0.1588 centimeter) and 0.5 inches (1.27 centimeters).

6. The multiple-choke housing assembly of claim 1, wherein each choke of the plurality of chokes comprises a plurality of windings.

7. The multiple-choke housing assembly of claim 6, wherein each winding of the plurality of windings is configured with a first extended lug on a first end of the winding and a second extended lug on a second end of the winding.

8. The multiple-choke housing assembly of claim 7, wherein the lid is configured with a plurality of openings.

9. The multiple-choke housing assembly of claim 8, wherein the first extended lug and the second extended lug are configured to extend through a respective opening of the plurality of openings.

10. The multiple-choke housing assembly of claim 1, wherein the lid is comprised of a non-conductive material.

11. The multiple-choke housing assembly of claim 1, wherein the housing comprises a set of threaded holes configured to mount the lid to the housing.

12. The multiple-choke housing assembly of claim 1, wherein the housing comprises a set of alignment tabs, wherein the lid comprises a set of alignment indents, and wherein the set of alignment tabs and the set of alignment indents are configured to align the lid with the housing.

13. A component within an aircraft, comprising:
a printed circuit board;
a multiple-choke housing assembly coupled to the printed circuit board, the multiple-choke housing assembly comprising:
a housing, the housing comprising a plurality of voids;
a plurality of chokes, each of plurality of voids configured to receive a choke of the plurality of chokes; and
a lid, the lid configured to couple to the housing and enclose the plurality of chokes.

14. The component of claim 13, wherein the housing is constructed from a material, and wherein the material is at least one of Aluminum, Magnesium, or Copper.

15. The component of claim 13, wherein each void in the plurality of voids comprises a shape to correspond to a shape of the choke that will reside therein, and wherein, responsive to the choke in the plurality of chokes being disposed in the void in the plurality of voids, aclearance is provided for securing the choke within the void, wherein the choke is secured within the void via a potting material.

16. The component of claim 13, wherein a first void of plurality of voids and a second void of the plurality of voids share a common wall and wherein a thickness of the common wall is between 0.0625 inches (0.1588 centimeter) and 0.5 inches (1.27 centimeters).

17. The component of claim 13, wherein each choke of the plurality of chokes comprises a plurality of windings, wherein each winding of the plurality of windings is configured with a first extended lug on a first end of the winding and a second extended lug on a second end of the winding, wherein the lid is configured with a plurality of openings, and wherein the first extended lug and the second extended lug are configured to extend through a respective opening of the plurality of openings.

18. The component of claim 13, wherein the lid is comprised of at least one of a polycarbonate; an epoxy; or a flame-resistant, fiberglass-reinforced epoxy laminate.

19. The component of claim 13, wherein the housing comprises at least one through hole configured for mounting the multiple-choke housing assembly to the printed circuit board.

20. The component of claim 13, wherein the housing comprises a set of threaded holes configured to mount the lid to the housing and wherein the housing comprises a set of alignment tabs, wherein the lid comprises a set of alignment indents, and wherein the set of alignment tabs and the set of alignment indents are configured to align the lid with the housing.
